(19) United States
(12) Patent Application Publication
(10) Pub. No.: US 2008/0116947 A1
(43) Pub. Date: May 22, 2008

(54) Method and Apparatus for Distributing Charge Pump Current and Voltage for PLL Circuits

(76) Inventors: Katherine Ellen Lobb, Marlborough, MA (US); James David Strom, Rochester, MN (US)

Correspondence Address: IBM CORPORATION;ROCHESTER IP LAW DEPT 917, 3605 HIGHWAY 52 N, ROCHESTER, MN, 55901-7829, US

(21) Appl. No.: 11/561,431

(22) Filed: Nov. 20, 2006

(51) Int. Cl. H03L 7/08

(52) U.S. Cl. 327/157

(57) ABSTRACT

A method and apparatus for distributing charge pump current and voltage for phase-locked loop circuits includes a charge pump implemented with a plurality of charge pump stages, each providing substantially equal charge pump current. Each stage includes a respective associated buffer for receiving an incoming increment (INC) signal and an incoming decrement (DEC) signal and providing an output time delayed INC signal and an output time delayed DEC. A chain of the buffers is provided to pass the time delayed INC signals and the time delayed DEC signals to the respective charge pump stages. Each of the charge pump stages includes an enable input arranged for independently enabling each respective charge pump stage.

### FIELD OF THE INVENTION

The present invention relates generally to the data processing field, and more particularly, relates to a method and apparatus for distributing charge pump current and voltage for phase-locked loop (PLL) circuits.

### DESCRIPTION OF THE RELATED ART

Phase-Locked Loop circuits are used in frequency synthesizers to provide an output signal that has a selectable, precise, and stable frequency with low frequency spurs and good phase noise. The phase-locked loop output signal may connect to the clock distribution of a games or server processor chip or provide the clock for a high speed 10 interface and many other applications.

When a PLL is locked, a simple phase-frequency detector can send out a small glitching pulse every reference clock cycle. The charge pump reacts to this glitch the same way it reacts to any other input, it changes the control voltage and current, which causes a glitch in the control voltage and charge pump current. This causes the VCO frequency to change.

One solution is to create a glitchless phase-frequency detector. However, the known glitchless phase-frequency detectors generally tend to be large and complex. Known glitchless phase-frequency detectors can also be sensitive to input rise and fall times and Integrated Circuit (IC) tracking. IC process tracking reduces the effectiveness of the glitchless or zero dead zone PFD in reducing the control voltage glitch that occurs when the PLL is locked.

A glitchless or zero dead zone PFD does not help control the voltage excursion that occurs when a frequency or phase error is introduced in the PLL causing the PFD to introduce a correction pulse. When this occurs, the PFD generates an increment (INC) or a decrement (DEC) Pulse proportional to the frequency or phase error. This pulse introduces an instantaneous shift in the control voltage, causing an instantaneous shift in the VCO frequency. The instantaneous change in the VCO frequency is integrated over the number of cycles the PLL is multiplying by so that the average frequency of VCO correlates to the reference clock. The instantaneous change in the VCO frequency also appears as jitter, which impacts the associated logic chips logic and input/output (IO) performance.

With the trends towards cheaper and lower reference generation modules and clock distribution the on chip, PLLs are increasingly required to provide high multipliers. With the high number of VCO cycles between PFD updates, the instantaneous shift in the control voltage and, hence, the VCO frequency and instantaneous jitter become significant.

A need exists for improved phase-locked loop circuits that include an effective mechanism for introducing the same average control voltage and frequency correction without the instantaneous control voltage and frequency shift and associated jitter of prior art arrangements.

### SUMMARY OF THE INVENTION

Principal aspects of the present invention are to provide a method and apparatus for distributing charge pump current and voltage for phase-locked loop circuits. Other important aspects of the present invention are to provide such method and apparatus for distributing charge pump current and voltage for phase-locked loop circuits substantially without negative effect and that overcome some disadvantages of prior art arrangements.

In brief, a method and apparatus are provided for distributing charge pump current and voltage for phase-locked loop circuits. A charge pump is implemented with a plurality of charge pump stages, each providing substantially equal charge pump current. Each stage includes a respective associated buffer for receiving an incoming increment (INC) signal and an incoming decrement (DEC) signal and providing an output time delayed INC signal and an output time delayed DEC. A chain of the buffers is provided to pass the time delayed INC signals and the time delayed DEC signals to the respective charge pump stages. Each of the charge pump stages includes an enable input arranged for independently enabling each respective charge pump stage.

In accordance with features of the invention, each stage in the charge pump switches at separate times, the total charge added to the loop filter is the same while the charge from a mismatch is 1/M of what it would be if all the charge pump stages were updated simultaneously, where M equals the number of charge pump stages.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is block diagram representation illustrating an exemplary phase-locked loop circuit in accordance with the preferred embodiment;

FIGS. 2A and 2B are block diagram representations together illustrating an exemplary distributed charge pump of the phase-locked loop circuit of FIG. 1 in accordance with the preferred embodiment;

FIGS. 3A and 3B are diagrams respectively illustrating control voltage resulting with the distributed charge pump of FIG. 2 in the phase-locked loop circuit of FIG. 1 in accordance with the preferred embodiment and with a conventional charge pump in a phase-locked loop circuit.

### DESCRIPTION OF THE PREFERRED EMBODIMENTS

In accordance with features of the invention, a method is provided for introducing a substantially same average control voltage and frequency correction, without the instantaneous control voltage and frequency shift and associated jitter.

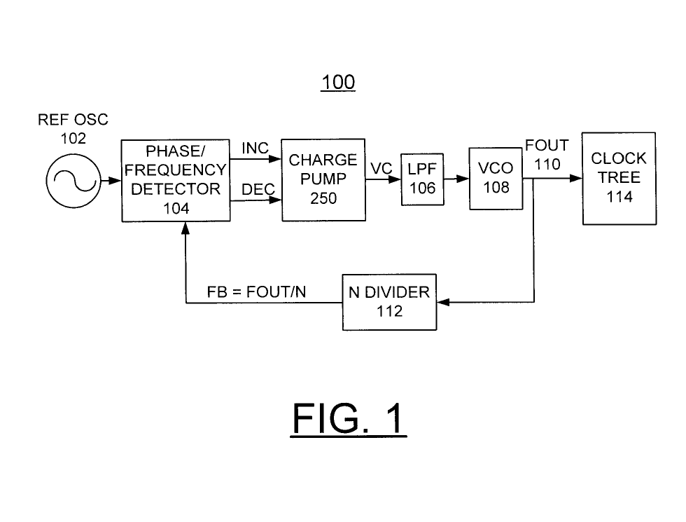

Having reference now to the drawings, in FIG. 1, there is shown an exemplary phase-locked loop circuit generally designated by the reference character 100 in accordance with the preferred embodiment. The phase-locked loop circuit 100 includes an input from a reference oscillator 102, a phase/frequency detector (PFD) 104, and a distributed charge pump 250 in accordance with the preferred embodiment. The phase-locked loop circuit 100 includes a low-pass filter (LPF) 106, a voltage-controlled oscillator (VCO) 108 providing a frequency output indicated by FOUT 110 and a feedback divider or N divider 112. A feedback signal FB of the N divider 112 equal to FOUT/N is applied to the phase/frequency detector (PFD) 104. The frequency output FOUT 110 of VCO 108 is applied to a clock tree 114.

In operation, the phase/frequency detector 104 receives and compares the reference signal and feedback signal, and generates an output pulse that is proportional to the phase difference between the input reference signal and the feedback signal FB fed back from the VCO 108 via N divider 112. The distributed charge pump 250 in accordance with the preferred embodiment then delivers either negative or positive charge pulses to the low-pass filter 106 depending on whether the reference signal phase leads or lags the phase of the feed back VCO output. These charge pulses are integrated by the low-pass filter 106 to generate a tuning voltage input into the VCO 108; the VCO's frequency moves up or down based upon the tuning voltage in order to synchronize with the reference signal.

Generally the tuning voltage from the loop filter 106 moves higher or more positive to advance the VCO's output phase and make its frequency higher and vice versa for the down voltages. The VCO output signal, FOUT, is related to the reference signal, FREF, by the relationship FOUT=N*FREF, where N is the feedback divider.

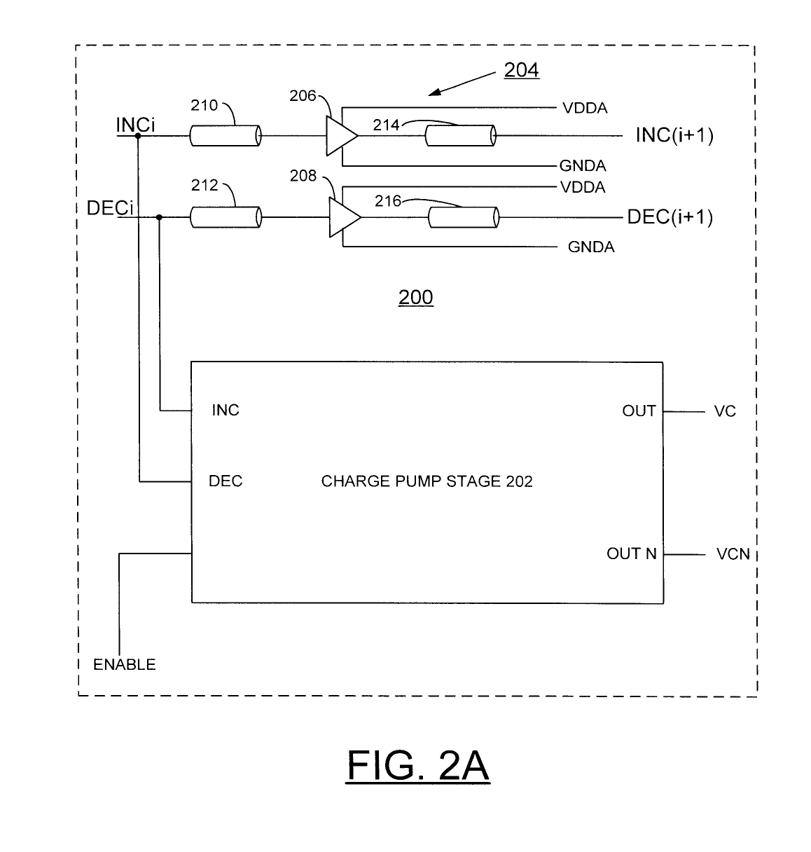

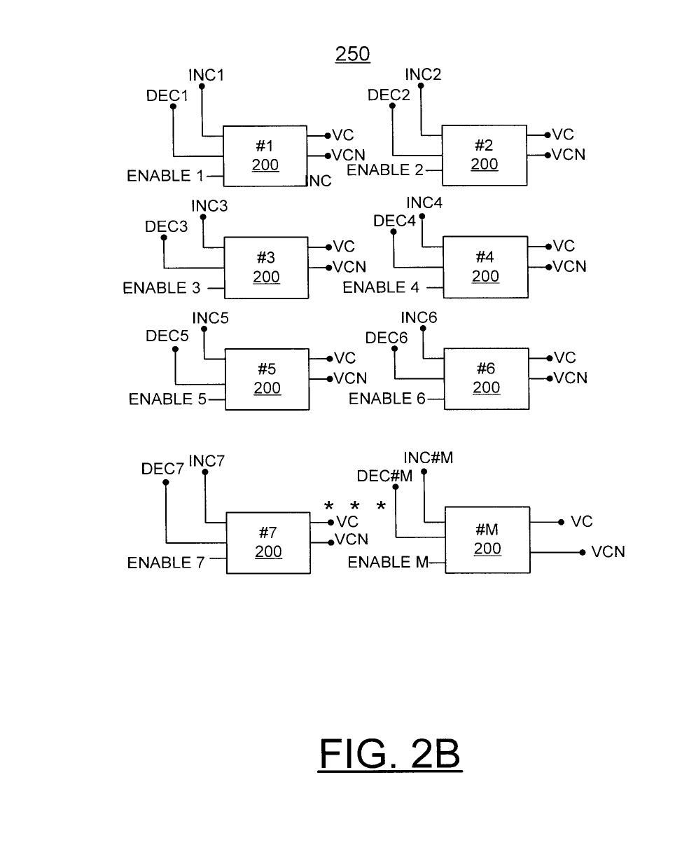

FIGS. 2A and 2B respectively illustrate an exemplary charge pump stage generally designated by the reference character 200 and the distributed charge pump 250 of the phase-locked loop circuit 100 in accordance with the preferred embodiment.

In accordance with features of the invention, distributed charge pump 250 is implemented with a plurality of charge pump stages 200, each providing substantially equal charge pump current. Each stage 200 includes a respective associated buffer for receiving an incoming increment (INC) signal and an incoming decrement (DEC) signal and providing an output time delayed INC signal and an output time delayed DEC. A chain of the buffers is provided to pass the time delayed INC signals and the time delayed DEC signals to the respective charge pump stages. Each of the charge pump stages includes an enable input arranged for independently enabling each respective charge pump stage.

In accordance with features of the invention, each stage 200 in the charge pump 250 switches at separate times, the total charge added to the loop filter is the same while the charge from a mismatch is 1/M of what it would be if all the charge pump stages were updated simultaneously, where M equals the number of charge pump stages.

Referring now to FIG. 2A, the charge pump stage 200 in accordance with the preferred embodiment includes a charge pump 202 and a time delay buffer or function generally designated by the reference character 204. Charge pump 202 receiving an incoming increment (INCi) signal and an incoming decrement (DECi) signal and an enable input ENABLE signal, and provides output OUT, VC and an inverter output OUT N, VCN. Time delay function includes a respective buffer 206, 208 receiving an incoming increment signal INCi and an incoming decrement signal DECi via a respective conductor or wire 210, 212 and providing an output time delayed increment signal INC(i+1) and an output time delayed decrement signal DEC(i+1) via a respective conductor or wire 214, 216. The time delay provided by buffers 206, 208 is a predefined or set time value, such as, 20 pico-seconds (ps).

Referring now to FIG. 2B, there are shown an exemplary distributed charge pump 250 includes a predetermined number M of parallel stages 200. For example, eight in the illustrated example, of parallel stages 200 are provided all delivering substantially equal amounts of charge pump current at outputs VC, VCN to LPF 106. The distributed charge pump 250 of the invention uses a chain of time delay buffers 204 to pass the increment (INC) and decrement (DEC) signals from the simple PFD 104 to each stage 200. Then each stage 200 having a time delay T of 20 ps, receives a respective INC and DEC signal after a time delay as follows:
Stage #1, 200 at time=0 ps
Stage #2, 200 at time=20 ps
Stage #3, 200 at time=40 ps
and the like.

While a PLL is in steady state the PFD 104 outputs substantially equal INC and DEC pulses, which are intended to cancel out each other. However, in practice there is always some mismatch between the INC and DEC pulses, and typically this generates jitter.

In the distributed charge pump 250 of the invention, each stage 200 in the charge pump 250 switches at separate times, the total charge added to the loop filter 106 is the same, while the charge from the mismatch is 1/M of what would result if all the charge pump stages 200 were updated simultaneously, where M represents the number of charge pump stages 200.

The ENABLE<1 to 8> selects can be enabled in any order but typically would be activated in ascending order. The delay of the respective buffers 206, 208 in each time delay function 204 is designed to be large as possible as long as their delay stays substantially higher than the PLL loop bandwidth. This is not an issue as the PLL loop bandwidths are typically a maximum of 30 MHz. The minimum delay of the buffers is greater than or equal to the dead zone delay of the PFD 104 in the PLL circuit 100, which in 90 nm CMOS technology is around 20 ps.

In accordance with features of the invention, the delay of the buffers 206, 208 is made large enough so that the width of the up and down pulses from the PFD 104 both while the PLL is in a steady state and during small loop corrections is smaller than the buffer delay. This delay of the buffers 206, 208 advantageously is tuned for each application or the delays could also be designed to be programmable and tuned for each application or the delays could also be set to zero.

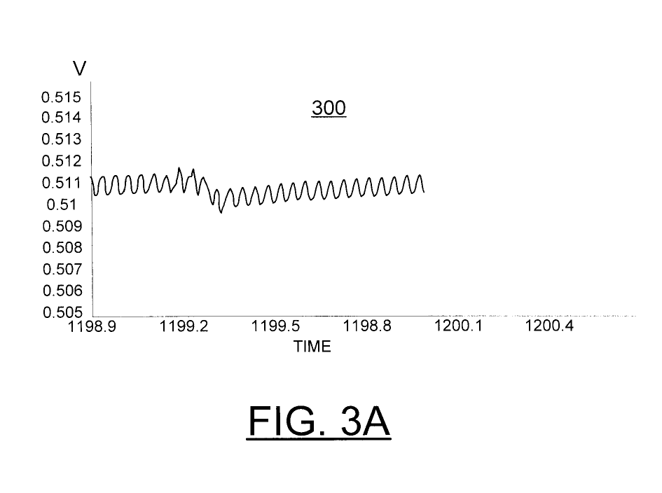

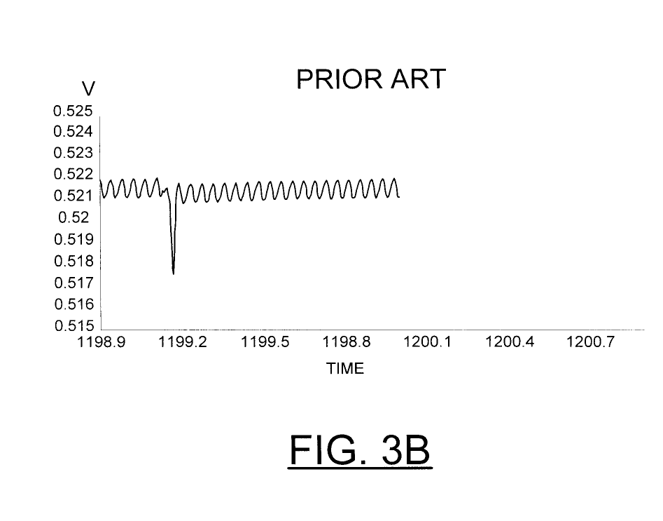

Referring now to FIG. 3A, there is shown an exemplary control voltage resulting with the distributed charge pump 250 of FIGS. 2A and 2B in the phase-locked loop circuit 200 in accordance with the preferred embodiment.

Referring also to FIG. 3B, an exemplary control voltage resulting with a conventional charge pump in a phase-locked loop circuit. In FIG. 3A and 3B, the illustrated control voltage corresponds to clock jitter.

The larger magnitude glitch on the control voltage corresponds to larger clock jitter in the conventional charge pump in a phase-locked loop circuit of FIG. 3B.

While the present invention has been described with reference to the details of the embodiments of the invention shown in the drawing, these details are not intended to limit the scope of the invention as claimed in the appended claims.

What is claimed is:

1. Apparatus for distributing charge pump current and voltage for phase-locked loop circuits comprising the steps of:
a charge pump including a plurality of charge pump stages, each said charge pump stage providing substantially equal average charge pump current;
each said charge pump stage including a time delay buffer function receiving an incoming increment (INC) signal and an incoming decrement (DEC) signal and providing an output time delayed INC signal and an output time delayed DEC;
said respective time delay buffer functions coupled in a chain for passing time delayed INC signals and the time delayed DEC signals to a next respective charge pump stage; and
each said charge pump stage including an independent enable input.

2. Apparatus for distributing charge pump current and voltage for phase-locked loop circuits as recited in claim 1 wherein said time delay buffer function has a predefined time delay, said predefined time delay being substantially equal for each of said plurality of charge pump stages.

3. Apparatus for distributing charge pump current and voltage for phase-locked loop circuits as recited in claim 1 wherein said time delay buffer function has a selected predefined time delay, said selected predefined time delay being greater than a dead zone delay of an associated phase/frequency detector (PFD) in the phase-locked loop circuit.

4. Apparatus for distributing charge pump current and voltage for phase-locked loop circuits as recited in claim 1 wherein each said time delay buffer function has a selected predefined time delay of approximately 20 pico-seconds.

5. Apparatus for distributing charge pump current and voltage for phase-locked loop circuits as recited in claim 1 wherein each respective said charge pump stage is enabled at a separate time.

6. Apparatus for distributing charge pump current and voltage for phase-locked loop circuits as recited in claim 5 where M represents a number of charge pump stages, and wherein a charge from a mismatch is represented by 1/M of a total charge added to an associated loop filter with all the charge pump stages updated simultaneously.

7. Apparatus for distributing charge pump current and voltage for phase-locked loop circuits as recited in claim 1 wherein said plurality of charge pump stages are arranged in parallel, and wherein each respective said charge pump stage is enabled at a separate time.

8. Apparatus for distributing charge pump current and voltage for phase-locked loop circuits as recited in claim 1 wherein said time delay buffer function has a predefined time delay represented by T and wherein said respective time delay buffer functions coupled in a chain for passing time delayed INC signals and the time delayed DEC signals to a next respective charge pump stage and said charge pump stages have a distributed time delay respectively represented by 0, T, 2T, 3T, 4T, . . . MT where M equals the number of charge pump stages.

9. Apparatus for distributing charge pump current and voltage for phase-locked loop circuits as recited in claim 10 wherein said each respective said charge pump stage is enabled at a separate time, wherein instantaneous control voltage shift is substantially eliminated.

10. A method for distributing charge pump current and voltage for phase-locked loop circuits comprising the steps of:
providing a charge pump including a plurality of parallel charge pump stages, each charge pump stage providing substantially equal charge pump current;
receiving an incoming increment (INC) signal and an incoming decrement (DEC) signal and providing an output time delayed INC signal and an output time delayed DEC with each of said plurality of charge pump stages;
passing the time delayed INC signals and the time delayed DEC signals to a next respective charge pump stage; and
independently enabling each respective charge pump stage at a separate time.
